(19) United States
(12) Patent Application Publication
(10) Pub. No.: US 2026/0339375 A1
(43) Pub. Date: Oct. 29, 2026

(54) SENSOR ASSEMBLY WITH VOLTAGE REFERENCE CIRCUIT

(71) Applicant: Knowles Electronics, LLC, Itasca, IL (US)

(72) Inventors: Sreenath Pariyarath, Karnataka (IN); Mark Niederberger, Einsiedeln (CH); Gururaj Ghorpade, Bangalore (IN)

(21) Appl. No.: 19/721,343

(22) Filed: Jun. 26, 2026

Related U.S. Application Data
(62) Division of application No. 18/950,025, filed on Nov. 16, 2024.

(30) Foreign Application Priority Data
Jul. 13, 2024 (IN) 202411053602

(51) Int. Cl. G05F 3/26; B81B 7/00

(52) U.S. Cl. CPC G05F 3/267; B81B 7/008

(57) ABSTRACT

A sensor assembly interface circuit has an analog frontend (AFE) amplifier or buffer located between and coupled to the input pad and output pad. The interface circuit still further has a band gap reference (BGR) circuit, which includes first and second transistors arranged in parallel between a shared voltage source and a substrate of the integrated circuit, and has a common control terminal coupled to the first and second transistors. The BGR circuit further includes first and second parasitic transistors at the substrate, the first parasitic transistor being complementary to and associated with the first transistor, and the second parasitic transistor being complementary to and associated with the second transistor. The interface circuit still further has a start-up circuit configured to turn OFF at least one of the first and second parasitic transistors during startup.

### BENEFIT AND PRIORITY CLAIM

This application claims priority to Indian Application No. 202411053602, filed Jul. 13, 2024, and is a divisional application of U.S. Patent Application No. 18/950,025, filed Nov. 16, 2024, the contents of which are incorporated by reference for all purposes as if fully set forth herein.

### FIELD OF THE DISCLOSURE

The present disclosure relates generally to sensor assemblies and more particularly to sensor assemblies comprising an electrical interface circuit including a voltage reference, and electrical circuits for such sensor assemblies.

### BACKGROUND

Sensor assemblies generally comprise a transducer element, like a microelectromechanical systems (MEMS) motor, coupled to an interface circuit that processes an electrical signal generated by the transducer element. Such sensors assemblies are typically integrated with a host device or system to sense voice, vibration, gas, humidity, and temperature among other conditions. The interface circuit is often implemented as an integrated circuit that requires a voltage reference to power various functional blocks. One such voltage reference is a band gap reference (BGR) circuit that provides a constant voltage independent of temperature changes, supply variations and circuit loading, among others. The BGR voltage is typically about 1.25 V and is generated within the circuit by summing a voltage proportional to absolute temperature (PTAT) and a voltage complementary to absolute temperature (CTAT), which are produced within the circuit. The inverse relation between the PTAT and CTAT voltages helps to minimize any temperature dependencies. In the BGR, the PTAT voltage is based on a difference in base-emitter voltages of two different-sized bipolar junction transistors (BJTs), and the CTAT voltage is based on the turn ON voltage threshold of one of these BJTs.

However, the BJTs can each have an associated parasitic complementary BJT device which couples to the substrate of the integrated circuit. Under some possible initial conditions during start-up, where residual charges may be present at one or more of the associated internal circuit nodes, the parasitic BJTs have the potential to turn ON and conduct current. This can result in current being drawn away from the base of the BJTs, which in turn, can impair the ability of the BJTs to initially turn ON. If the BJTs are precluded from turning ON, the circuit's ability to generate an intended voltage reference can be affected. Thus, there is an ongoing need for improvements in BGR circuits generally and for the application of such circuits in MEMS sensors.

### SUMMARY

The present application provides a sensor assembly. The sensor assembly includes a transducer element disposed in a housing, and an interface circuit disposed in the housing and having an input pad coupled to the transducer element, and an output pad coupled to a host-interface of the housing. The interface circuit further has an analog frontend (AFE) amplifier or buffer located between and coupled to the input pad and output pad. The interface circuit still further has a band gap reference (BGR) circuit, which includes first and second transistors arranged in parallel between a shared voltage source and a substrate of the integrated circuit, and having a common control terminal coupled to the first and second transistors. The BGR circuit further includes first and second parasitic transistors at the substrate, the first parasitic transistor being complementary to and associated with the first transistor, and the second parasitic transistor being complementary to and associated with the second transistor. The interface circuit still further has a start-up circuit configured to turn OFF at least one of the first and second parasitic transistors during startup. An output of the BGR circuit is coupled to the AFE amplifier or buffer.

According to another possible embodiment, a sensor assembly interface circuit is provided. The sensor assembly interface circuit includes an input pad connectable to a transducer element. The sensor assembly interface circuit further including an analog front end amplifier or buffer coupled to the input pad and to an output pad of the interface circuit. The sensor assembly interface circuit still further including a band gap reference circuit. The band gap reference circuit has first and second transistors arranged in parallel between a shared voltage source and an associated circuit substrate, each of the first and second transistor being respectively associated with a corresponding parasitic transistor. The band gap reference circuit further has one or more switches, each of which is associated with a corresponding one of the first and second parasitic transistors, which when closed, in response to an activation of a start-up signal upon initiation of the band gap reference circuit, are respectively configured and arranged to maintain in an OFF state the associated parasitic transistor.

According to another possible embodiment, a band gap reference circuit is provided. The band gap reference circuit includes a pair of transistors including a first transistor and a second transistor, where each of the first transistor and the second transistor is coupled between a source voltage and a substrate voltage, and where a control terminal of the first transistor is coupled to a control terminal of the second transistor, wherein at least one of the first transistor and the second transistor is associated with a parasitic transistor, which when active, biases the voltage of the control terminal of the associated transistor toward the voltage of the substrate. The band gap reference circuit further includes a start-up switch, which when closed, more strongly couples the control terminal of the transistor associated with the parasitic transistor to the source voltage thereby turning OFF the parasitic transistor and precluding any bias being produced by the parasitic transistor at the control terminal of the associated transistor. The band gap reference circuit produces a reference voltage at the control terminals of the first transistor and the second transistor, which is used to produce a regulated band gap reference output voltage.

These and other objects, features, and advantages of the present application will become more fully evident from the following description of one or more preferred embodiments and appended claims, with reference to the accompanying drawings. The drawings depict only representative embodiments and are not considered to limit the scope of the disclosure.

### BRIEF DESCRIPTION OF THE DRAWINGS

FIG. 1 is a cross sectional side view of an exemplary sensor assembly;

FIG. 2 is an exemplary electrical block diagram of the sensor assembly;

FIG. 3 is a simplified circuit schematic of an exemplary band gap reference circuit;

FIG. 4 is a cross sectional side view of an exemplary vertical NPN bipolar junction transistor, which could be used as part of a band gap reference circuit;

FIG. 5 is a top plan view of the exemplary vertical NPN bipolar junction transistor, illustrated in FIG. 4;

FIG. 6 is an electrical circuit schematic model of the exemplary vertical NPN bipolar junction transistor with corresponding parasitic transistor, illustrated in FIGS. 4 and 5;

FIG. 7 is a circuit schematic of a band gap reference circuit with start-up control for suppressing the effects of parasitic transistors, in accordance with at least one embodiment of the present application; and

FIG. 8 is a flow diagram of a method for suppressing the effects of parasitic transistors in a band gap reference circuit, in accordance with at least one embodiment of the present application.

Those of ordinary skill in the art will appreciate that the figures are illustrated for simplicity and clarity and therefore may not be drawn to scale and may not include some well-known features. For example, the dimensions of some of the elements in the drawings may be exaggerated relative to other elements with the intent to help improve understanding of the aspects of the embodiments being illustrated and described. Further, the order of occurrence of actions or steps in any described methods may be different than the order described, the order of occurrence of such actions or steps may be performed concurrently unless specified otherwise, and the terms and expressions used herein will generally have meanings understood by those of ordinary skill in the art except where a different meaning is specifically attributed to them, herein.

### DETAILED DESCRIPTION

The disclosure relates generally to sensor assemblies and more particularly to sensor assemblies comprising an electrical interface circuit with a band gap reference circuit, and electrical interface circuits for such sensor assemblies, which include the band gap reference circuit.

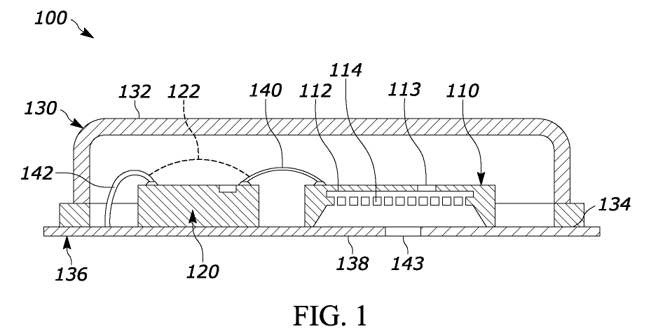

In FIG. 1, a sensor assembly 100 comprises a transducer element (also referred to herein as a “motor”) 110, which is electrically coupled to an input pad or node of an electrical interface circuit (also referred to herein as an “interface circuit”, “electrical circuit” or “circuit”) 120 within a housing 130. The representative housing includes a cover 132 fastened to a surface 134 of a base 136. The transducer element and electrical circuit can both be fastened to the base or to the cover, or one to the cover and the other to the base. The housing can shield the transducer element and the electrical circuit located within its interior from external electromagnetic interference, like RF noise. For this purpose, the cover can be a metal can or a non-conductive material, like plastic or FR4, covered by a conductive material electrically coupled to a conductive portion (e.g., a ground plane) of the base. The housing can also include an interface with contacts configured to interface with a host device. Such an interface is also referred to herein as a “host-interface”.

The sensor assembly can be configured for mounting to a host device by reflow soldering, pin-grid array or via through-hole mounting, among other known and future mounting techniques. The host device can include a PCB or flex PCB to which the sensor assembly is fastened, as described herein. In FIG. 1, the sensor assembly is a surface-mount device comprising a host-interface including electrical contacts (e.g., ground, power, data, clock, select…) located on an outer surface 138 of the base 136. The electrical circuit can transmit data and other information and obtain power, clock, control and other signals via contacts of the host-interface. The electrical circuit is coupled to the transducer element via one or more leads 140 and to contacts on the host-interface via one or more leads 142 connected to traces (not shown) integrated with the base for this purpose. The electrical circuit can be implemented as an integrated circuit (IC) that can be covered by an encapsulating material 122 to regulate heat dissipation.

In one embodiment, the sensor assembly is a microphone configured to generate an electrical signal representative of acoustic signals, or sounds, propagated through the atmosphere and detected by the transducer element. In other embodiments, the sensor assembly is a vibration sensor that generates an electrical signal representative of vibrations or forces detected by the transducer element. Such a vibration sensor can detect vibrations propagated through a person’s body tissue or through inanimate objects. Other sensor assemblies can detect pressure, acceleration, humidity, or temperature, among other conditions. A single sensor assembly can comprise multiple transducer elements to detect corresponding conditions, like sound and vibration, among other combinations. Such multiple transducer elements can be discrete devices or can be integrated as a unitary device.

In some sensor assemblies, like microphones, the housing includes an aperture (also referred to herein as a “sound port” or “port”) connecting the interior of the housing to the external environment. In FIG. 1, the port 143 is located on the base 136 in alignment with the transducer element 110. In a top-port sensor assembly, the port can be located on the cover. In other sensor assemblies requiring a port, the port can be located on a sidewall of the housing. A port is not required in some sensor assemblies, like at least some acoustic vibration sensors and accelerometers, among others.

In one implementation, the transducer element is a capacitive device. Alternatively, the transducer element can be a piezo, optical, or resonant device, among others. The transducer element can be implemented using micro-electro-mechanical systems (MEMS) or some other known or future technology. In FIG. 1, the representative transducer element 110 is a capacitive device comprising a diaphragm 112 spaced apart from, and electrically biased relative to, a perforated back plate 114. A pressure equalization vent 113 formed in the diaphragm can be configured to set a low frequency roll off (LFRO) of the transducer element. Other capacitor transducer elements can have other forms. Sound pressure entering the housing via sound port 143 displaces the diaphragm producing an electrical signal representative of acoustic pressure variations. The bias voltage can be provided by a charge pump of the electrical circuit. Other transducer elements may not require a bias voltage and thus a charge pump may not be required.

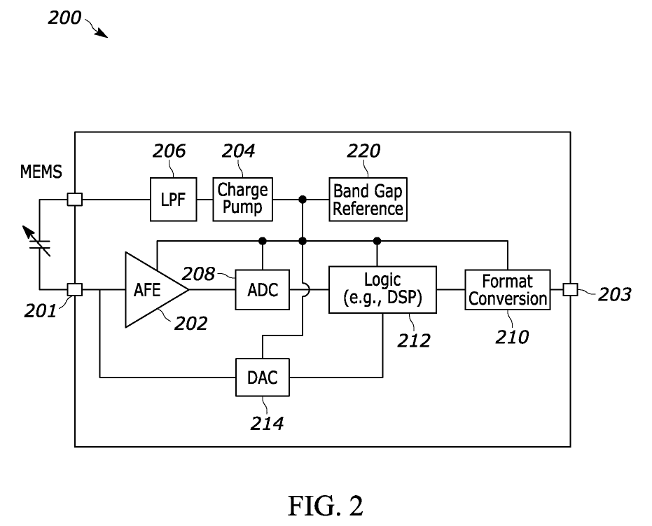

The electrical circuit generally comprises an analog front end (AFE) amplifier or buffer in a forward signal-path between an input and output nodes (also referred to as “pads”) of the electrical circuit. The input node of the electrical circuit is connectable to the transducer element when integrated with the sensor assembly. The output node is connectable to the host-interface when the electrical circuit is integrated with the sensor assembly. In FIG. 2, the electrical circuit 200 comprises an AFE amplifier or buffer 202 in a forward signal-path between an input pad 201 and an output pad 203 of the electrical circuit. The input pad is also coupled to a transducer, for example, the capacitive MEMS motor 110 of FIG. 1. The forward signal-path can also include other functional blocks, examples of which are described further herein. In sensor assemblies comprising a transducer element that uses a bias voltage, the electrical circuit can include a charge pump 204 and a low-pass filter 206 coupled to the input pad. One such transducer element that requires a bias voltage is a capacitive motor. Capacitive motors and other transducer elements may also require that the AFE amplifier or buffer have a high input resistance (e.g., 300 T ohms or more) to prevent or limit charge leakage. Other electrical circuits do not require a bias voltage source or a high input resistance. The charge pump and filter are not required in implementations that do not require a bias voltage.

In digital interface circuits, an analog-to-digital converter (ADC) 208 is coupled to an output of the AFE amplifier or buffer. The forward signal-path can also include a data format conversion block 210 to convert the digital output from the ADC to a different format (e.g., PCM to PDM, I2S or SoundWire, among other known and future formats). In some implementations, the interface circuit also comprises a digital servo-loop (DSL) comprising a logic circuit 212 (e.g., a DSP) configured to generate and provide a pulse width or amplitude modulated (PWAM) signal to a digital-to-analog (DAC) converter 214 coupled to the input of the AFE amplifier or buffer. The PWAM is proportional to an output of the ADC. The DSL can regulate the voltage at the input of the AFE amplifier or buffer and can control the LFRO.

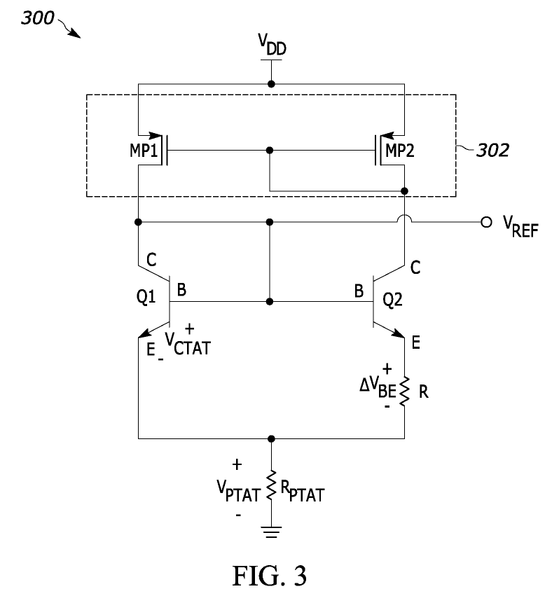

In FIG. 2, the interface circuit 200 also comprises a BGR circuit that provides a relatively stable reference voltage independent of temperature changes, supply variations and circuit loading among others to various functional blocks of the interface circuit. FIG. 3, illustrates a simplified circuit schematic of an exemplary BGR circuit 300. In the illustrated embodiment, the BGR circuit 300 comprises a pair of transistors including a first transistor Q1 and a second transistor Q2, which are arranged in parallel between a shared voltage source V_{DD} and a substrate of the integrated circuit. In the illustrated embodiment, both the first transistor Q1 and the second transistor Q2 are NPN bipolar junction transistors (BJTs). The base of the first transistor Q1 is coupled to the base of the second transistor, thereby forming a common terminal, which serves as a control terminal for both transistors Q1 and Q2. The common control terminal is similarly coupled to an output port, which defines a reference voltage output V_{REF}. The emitters of both the first transistor Q1 and the second transistor Q2 are coupled to the circuit substrate via a resistor R_{PTAT}. In the illustrated embodiment, the emitter of the second transistor is coupled to resistor R_{PTAT} via a further resistor R. Resistor R represents a purposeful difference in the base-emitter voltages of the two transistors Q1 and Q2, which is used to help define the value of the reference voltage being produced. The collector of each of the first transistor Q1 and the second transistor Q2 are coupled to the shared voltage source V_{DD} via a current mirror 302. More specifically, the current mirror 302 includes a pair of PMOS transistors MP1 and MP2 for respectively coupling the emitters of the first transistor Q1 and the second transistor Q2 to shared voltage source V_{DD}. The gate of PMOS transistor MP1 is coupled to both the gate and the drain of PMOS transistor MP2.

Together the PMOS transistors of the current mirror produce an equivalent current which is then respectively supplied to each of the first and second NPN BPJs Q1 and Q2. Due to the difference in the respective base-emitter voltages of the first transistor Q1 and the second transistor Q2 a ΔV_{BE} and consequently a PTAT voltage is established. In the illustrated embodiment, the CTAT voltage corresponds to base emitter voltage of the first transistor Q1. The reference voltage V_{REF} is the sum of the PTAT voltage, which is proportional to absolute temperature, and the CTAT voltage, which is complementary to absolute temperature. Together the two voltages contribute to a reference voltage V_{REF} that is relatively temperature stable. The temperature stable voltage reference can be used to formulate a reference voltage, which can be used to provide a more stable supply voltage to other circuit elements, such as to the amplifier 202, the analog to digital converter 208, the charge pump 204, logic circuitry 212, the digital servo loop (DSL) DAC 214, and/or the format conversion circuit 210 of the electrical circuit interface 200 of FIG. 2, as well as any other circuit elements that might benefit from receiving a temperature stable voltage reference. The BGR circuit illustrated in FIG. 3 is consistent with the type of BGR circuit, which is identified as a band gap reference circuit that has a Brokaw based architecture.

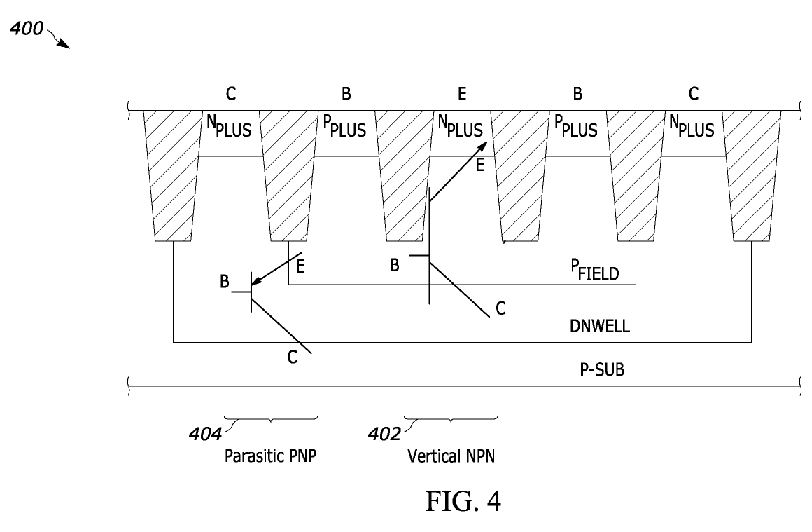

FIG. 4 illustrates a cross sectional side view 400 of an exemplary vertical NPN bipolar junction transistor, which could be used in a band gap reference circuit. In at least some instances, a vertical type BJT may be preferred for use, because of its better beta value. In the illustrated embodiment, the bipolar junction transistor provides for an N-plus doped region in the center of a P-Field region, which in turn sits within a deep N well (DNWELL), above a P type Substrate (P-SUB). The connection to the N-plus doped region can provide a connection which serves as the emitter of the transistor. Further, a connection to the P-Field via a P-plus doped region near the surface can provide a connection, which serves as the base of the transistor. Still further, a further N-plus doped region, near the surface of the DNWELL can serve as the collector of the transistor. Together, the N-plus doped region, the P-SUB, and the DNWELL form a corresponding vertical NPN type bipolar junction transistor 402. However, the stack up further includes a P type Substrate, which in conjunction with the DNWELL and the P-Field corresponds to a PNP configuration, which forms a parasitic PNP transistor 404 that may similarly be present.

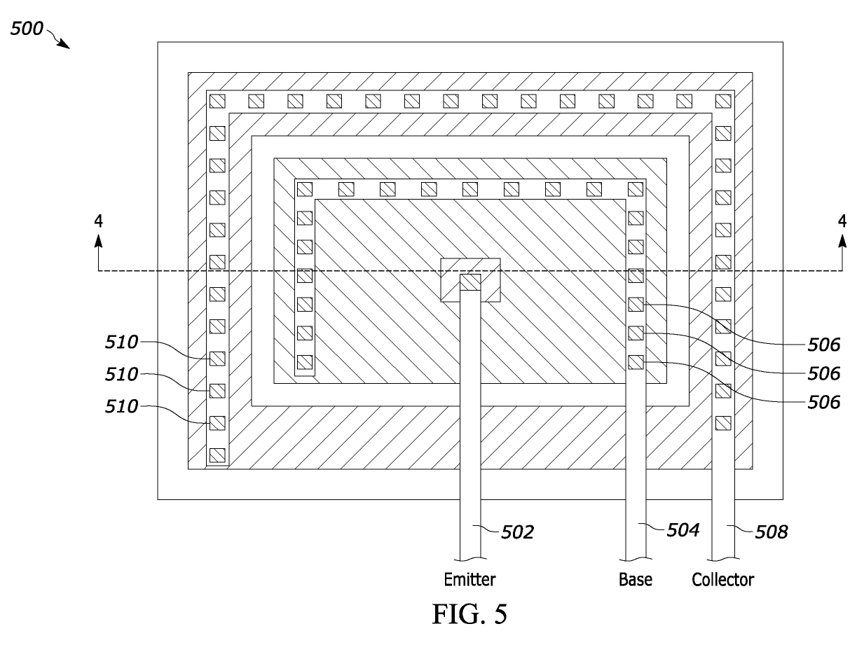

While a pair of B-plus regions are identified as being associated with the base of the transistor, and a pair of N-plus regions are identified as being associated with the collector of the transistor, in the illustrated embodiment, the respective pairs of regions are each part of a ring region that corresponds to an electrically shared section that surrounds an electrically distinct interior space. For example, the base forms a ring that encompasses the emitter, and the collector forms a ring that encompasses the base, as well as the emitter. The corresponding rings can be better seen in FIG. 5, which illustrates a top plan view 500 of the exemplary vertical NPN bipolar junction transistor, illustrated in FIG. 4.

In FIG. 5 there are multiple distinct concentric ring regions and a center region, which alternate between p-type and n-type regions. A metalized layer, which includes multiple separate traces, respectively connect to the electrically distinct regions. For example, a trace 502, corresponding to the emitter of the associated transistor, is coupled to the center N-plus doped region. A further trace 504, corresponding to the base of the associated transmitter, is coupled to the inner ring associated with the P-Field region, which extends around the center region. The trace 504 extends at least partly around the inner ring, making multiple connection 506 to the underlying P-Field P type region. A still further trace 508, corresponding to the collector of the associated transmitter, is coupled to the outer ring associated with the DNWELL region, which extends around the center region and the inner ring. The trace 508 extends at least partly around the outer ring, making multiple connection 510 to the underlying DNWELL N type region. As noted above, the additional inclusion of a P type Substrate P-SUB results in a corresponding parasitic P type transistor 404. The corresponding parasitic transistor 404 has an emitter, which shares a connection with the base of transistor 402. Further, the corresponding parasitic transistor 404 has a base, which shares a connection with the collector of transistor 402. The collector of the parasitic transistor 404 is coupled to the P type Substrate P-SUB.

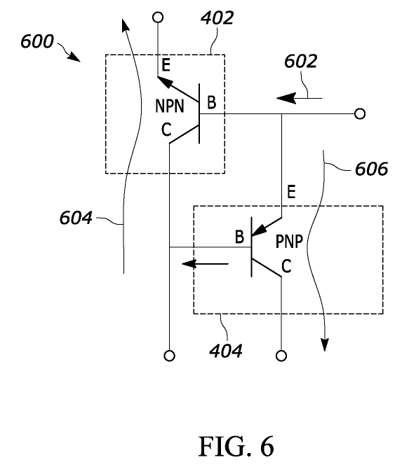

FIG. 6 illustrates an electrical circuit schematic model 600 of the exemplary vertical NPN bipolar junction transistor with corresponding parasitic transistor, that is shown in FIGS. 4 and 5. Transistor 402 and corresponding parasitic transistor 404 are arranged, such that generally, only one of them will be ON at the same time. In other words, if one of them turns ON, the other one will generally be precluded from turning ON and/or will be maintained in an OFF state. This is because, the ON state for each of the transistors will generally create a condition in which the other transistor will not turn ON. For example, NPN BPJ transistor 402 will generally turn ON if the voltage at the base is greater than the voltage of the emitter by at least an amount corresponding to the associated threshold voltage. For the parasitic PNP BPJ transistor 404, the transistor will generally turn ON if the voltage at the base is less than the voltage of the emitter by at least an amount corresponding to the threshold voltage. When the NPN BPJ transistor 402 turns ON, current will flow 602 into the base, which will allow current to flow 604 from the collector to the emitter. In turn, this will cause the voltage at the base of the parasitic transistor 404 to increase and the voltage at the emitter of the parasitic transistor 404 to decrease, which will likely be maintained at a level the fails to meet the threshold voltage necessary for turning ON. The same is generally true with respect to the parasitic transistor 404, where if it ever turns ON, it will draw 606 current away from the base of the NPN BPJ transistor, thereby limiting the ability of the base of the NPN BPJ transistor 402 from ever rising to the level above the voltage of the emitter to allow the transistor 402 to turn ON. During the start-up of the band gap reference circuit, it is generally unknown what voltage/charge, if any, is present on any of the transistor nodes. So, it is possible that initial conditions could support the parasitic transistor 404 turning ON, which could then limit the ability of the non-parasitic transistor 402 from being able to turn ON. The non-parasitic transistors Q1 and Q2 of the BGR circuit are generally both in an ON state when the circuit is producing a corresponding voltage reference signal during normal expected operation.

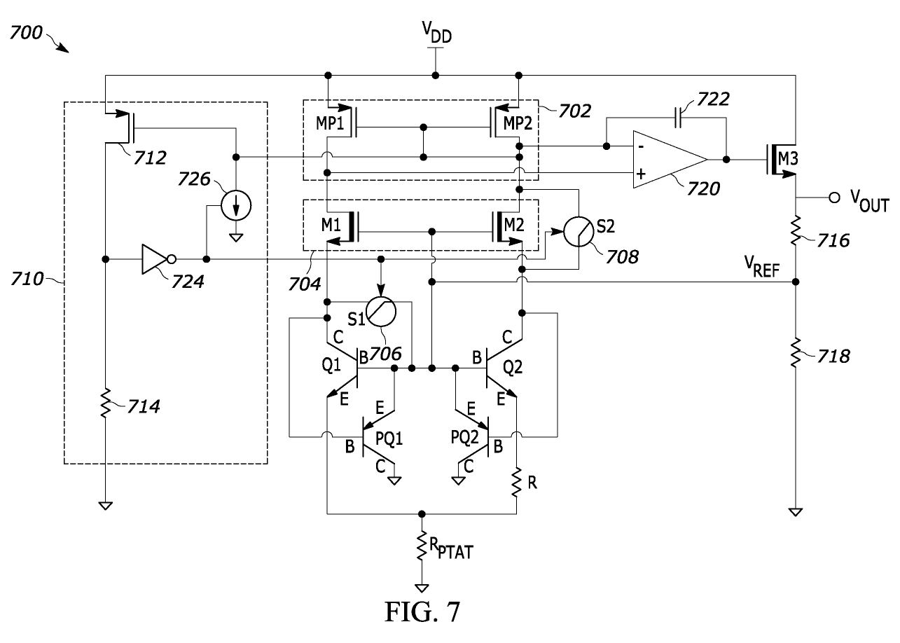

FIG. 7 illustrates a circuit schematic of a band gap reference circuit 700 with start-up control for suppressing the effects of parasitic transistors, in accordance with at least one embodiment of the present application. More specifically, the band gap reference circuit 700, which is illustrated in FIG. 7, is a more developed version of the band gap reference circuit 300, which is illustrated in FIG. 3. For example, in this version of the circuit, the band gap reference circuit expressly shows first and second parasitic transistors PQ1 and PQ2, that are associated with first and second transistors Q1 and Q2, as well as includes additional elements in support of a start-up circuit, which is configured to turn OFF at least one of the first and second parasitic transistors during startup. Similar to the arrangement illustrated in FIG. 6, each of the first and second transistors Q1 and Q2 has an associated parasitic transistor PQ1 and PQ2, where the emitter of the parasitic transistor is coupled to the base of the associated transistor, base of the parasitic transistor is coupled to the collector of the associated transistor, and the collector of the parasitic transistor is coupled to the substrate.

While in FIG. 3, the first and second transistors Q1 and Q2 are coupled to the voltage source V_{DD} via a current mirror 702, which includes MP1 and MP2, in FIG. 7, the first and second transistors Q1 and Q2 are coupled to the current mirror 702, via a cascade circuit 704. The cascade circuit 704 includes a pair of NMOS transistors M1 and M2, which are each respectively associated with a corresponding one of the first and second transistors Q1 and Q2. More specifically, the source of NMOS transistor M1 is coupled to the collector of the first transistor Q1, and the drain of the NMOS transistor M1 is coupled to the drain of the PMOS transistor MP1 of the current mirror 702. Further, the source of NMOS transistor M2 is coupled to the collector of the first transistor Q2, and the drain of the NMOS transistor M2 is coupled to the drain of the PMOS transistor MP2 of the current mirror 702. The gates of both NMOS transistors M1 and M2 are coupled together, as well as being coupled to the common control terminal for both transistors Q1 and Q2, which are associated with the base of each of bi-polar junction transistors Q1 and Q2.

To suppress parasitic transistors PQ1 and PQ2 the band gap reference circuit 700 includes a first switch 706 that is activated (i.e., closed) during start up, which when active shorts the base of the parasitic transistor PQ1 to the emitter of the parasitic transistor PQ1 through the switch 706. By shorting the base and the emitter of the parasitic transistor, the turn on threshold voltage, which corresponds to the voltage across the base and the emitter, can never be exceeded. In turn, this would preclude the transistor PQ1 from turning on, while the first switch 706 was closed. In the illustrated embodiment, the band gap reference circuit 700 includes a second switch 708, which is also activated (i.e., closed) during start up, which when active shorts the source and the drain of the cascade transistor M2, that is associated with the second transistor Q2 of the cascade circuit 704. The second switch 708 being closed, would more closely couple the collector of the transistor Q2, and correspondingly the base of the associated parasitic transistor PQ2 to the voltage source V_{DD}, which in turn would restrict the ability of the voltage of the base of the associated parasitic transistor PQ2 from being allowed to go too low, which similarly would negatively impact the ability of the parasitic transistor from being able to turn ON during startup.

The control terminals of the switches 706 and 708 are coupled to a start-up signal, which is produced by the startup signal generation circuit 710. The startup signal generation circuit 710 includes a PMOS transistor 712 in series with a resistor 714, which are coupled between the voltage source V_{DD} and the substrate via further resistor R_{PTAT}. More specifically, the source of the transistor 712 is coupled to the voltage source, and the drain of the transistor 712 is coupled to the resistor 714. A node coupled to the drain of the transistor 712 produces the start-up signal, which during start-up has a voltage value that is initially closer to the source potential, by being weakly pulled low via resistor 714 and resistor R_{PTAT}. However, the start-up signal is coupled to the gate of the PMOS transistor 712, which when low causes the PMOS transistor 712 to turn on, and thereby causing the node associated with the start-up signal to be more strongly coupled to the voltage source V_{DD}. The start-up signal in addition to being coupled to the control terminal of the switches 706 and 708 is coupled to the gates of current mirror transistors MP1 and MP2, as well as the drain of current mirror transistor MP2. By initially limiting the ability of the parasitic transistors PQ1 and PQ2 to be able to turn on during start up, the first and second transistors Q1 and Q2 are allowed to become active and facilitate the expected functioning of the band gap reference circuit in producing a desired reference voltage before the parasitic transistors have a chance to turn ON and negatively affect the functioning of the same.

In the illustrated embodiment, an output reference voltage V_{OUT} can be generated from the reference voltage using a voltage divider resistor network including resistors 716 and 718, which is coupled to the voltage source via a depletion mode NMOS transistor M3. The gate of the NMOS transistor M3 is coupled to the output of a differential op amp 720, which can be used to control the conduction of NMOS transistor M3. A capacitor 722 is coupled between the negative input and the output of the differential op amp 720. The positive input of the differential op amp 720 is coupled to the drain of the current mirror transistor MP1 and the drain of the cascade circuit transistor M1. The negative input of the differential op amp 720 is coupled to the drain of the current mirror transistor MP2 and the drain of the cascade circuit transistor M2. When transistor M3 is allowed to conduct current, the voltage level of the reference voltage controls the amount of current which flows through resistor 718, and correspondingly R_{PTAT}. In turn, this same current produces a further voltage drop across resistor 716, which results in the creation of an output voltage that can have a value that is higher than the internally produced reference voltage V_{REF}. Generally, the value of the output voltage Vout will be a function of the value of the reference voltage (V_{OUT} = αV_{REF}, where the value α is related to the values of the resistors in the voltage divider network). In turn, this allows the band gap reference circuit 700 to produce an output reference voltage, that is resistant to temperature fluctuations, while at the same time limiting the ability of the parasitic transistors PQ1 and PQ2 to potentially negatively affect the operation of the circuit 700.

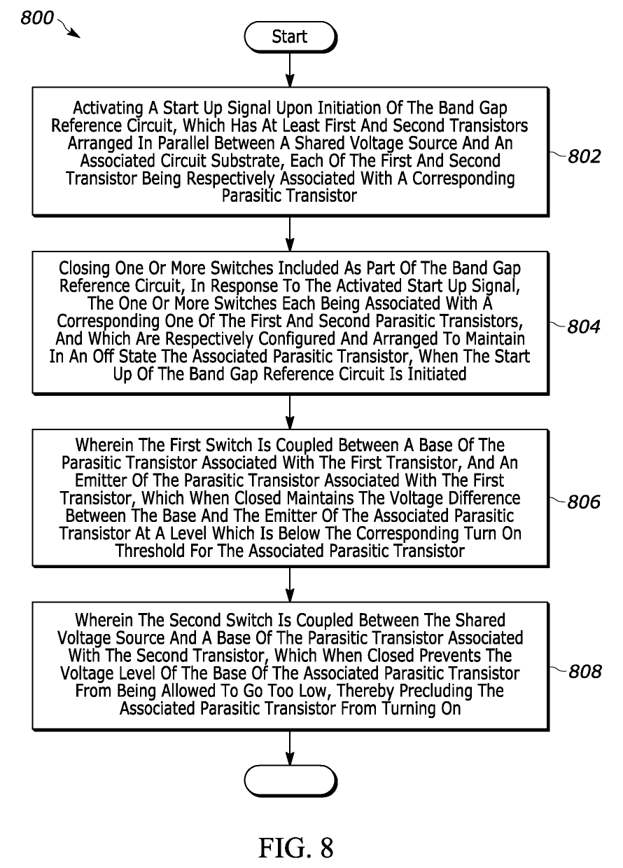

FIG. 8 illustrates a flow diagram of a method 800 for suppressing the effects of parasitic transistors in a band gap reference circuit, in accordance with at least one embodiment of the present application. The method includes activating 802 a start-up signal upon initiation of the band gap reference circuit, which has at least first and second transistors arranged in parallel between a shared voltage source and an associated circuit substrate. Each of the first and second transistor is respectively associated with a corresponding parasitic transistor. One or more switches included as part of the band gap reference circuit are closed 804, in response to the activated start up signal, the one or more switches each being associated with a corresponding one of the first and second parasitic transistors, and which are respectively configured and arranged to maintain in an off state the associated parasitic transistor, when the start-up of the band gap reference circuit is initiated. The first switch is coupled between a base of the parasitic transistor associated with the first transistor, and an emitter of the parasitic transistor associated with the first transistor, which when closed maintains the voltage difference between the base and the emitter of the associated parasitic transistor at a level which is below the corresponding turn on threshold for the associated parasitic transistor 806. The second switch is coupled between the shared voltage source and a base of the parasitic transistor associated with the second transistor, which when closed prevents the voltage level of the base of the associated parasitic transistor from being allowed to go too low, thereby precluding the associated parasitic transistor from turning on 808.

It should be understood that, notwithstanding the particular steps shown in the figures, a variety of additional or different steps can be performed depending upon the embodiment, and one or more of the particular steps can be rearranged, repeated or eliminated entirely depending upon the embodiment. Also, some of the steps performed can be repeated on an ongoing or continuous basis simultaneously while other steps are performed. Furthermore, all or portions of different steps can be performed by different elements or by a single element of the disclosed embodiments.

For at least some embodiments, at least some methods or portions thereof in this disclosure can be implemented on or under the control of a programmed processor or controller. However, the controllers, flowcharts, and modules may also be implemented on or under the control of a general purpose or special purpose computer, a programmed microprocessor or microcontroller and peripheral integrated circuit elements, an integrated circuit, a hardware electronic or logic circuit such as a discrete element circuit, a programmable logic device, or the like.

At least some embodiments can improve operation of the disclosed devices. Also, while this disclosure has been described with specific embodiments thereof, it will be evident that many alternatives, modifications, and variations will be apparent to those skilled in the art. For example, various components of the embodiments may be interchanged, added, or substituted in the other embodiments. Also, all elements of each figure are not necessary for operation of the disclosed embodiments. For example, one of ordinary skill in the art of the disclosed embodiments would be enabled to make and use the teachings of the disclosure by simply employing the elements of the independent claims. Accordingly, embodiments of the disclosure as set forth herein are intended to be illustrative, and not limiting. Various changes may be made without departing from the spirit and scope of the disclosure.

In this document, relational terms such as "first," "second," and the like may be used solely to distinguish one entity or action from another entity or action without necessarily requiring or implying any actual such relationship or order between such entities or actions. The phrase "at least one of," "at least one selected from the group of," or "at least one selected from" followed by a list is defined to mean one, some, or all, but not necessarily all elements in the list. The terms "comprises," "comprising," "including," or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by "a," "an," or the like does not, without more constraints, preclude the existence of additional identical elements in the process, method, article, or apparatus that comprises the element. Also, the term "another" is defined as at least a second or more. The terms "including," "having," and the like, as used herein, are defined as "comprising." Furthermore, the background section is written as the inventor's own understanding of the context of some embodiments at the time of filing and includes the inventor's own recognition of any problems with existing technologies and/or problems experienced in the inventor's own work.

1. A sensor assembly interface circuit including an input pad connectable to a transducer element, the sensor assembly interface circuit comprising:
an analog front end amplifier or buffer coupled to the input pad and to an output pad of the interface circuit;
a band gap reference circuit comprising
first and second transistors arranged in parallel between a shared voltage source and an associated circuit substrate, each of the first and second transistors being respectively associated with a corresponding parasitic transistor; and
one or more switches, each being associated with a corresponding one of the first and second parasitic transistors, which when closed, in response to an activation of a start up signal upon initiation of the band gap reference circuit, are respectively configured and arranged to maintain in an OFF state the associated parasitic transistor.

2. The sensor assembly interface circuit of claim 1, wherein a first switch of the one or more switches is coupled between a base of the corresponding parasitic transistor associated with the first transistor, and an emitter of the corresponding parasitic transistor associated with the first transistor, which when closed maintains a voltage difference between the base and the emitter of the associated parasitic transistor at a level which is below the corresponding turn ON threshold for the associated parasitic transistor, and wherein a second switch of the one or more switches is coupled between the shared voltage source and a base of the corresponding parasitic transistor associated with the second transistor, which when closed prevents a voltage level of the base of the associated parasitic transistor from being allowed to go too low, thereby precluding the associated parasitic transistor from turning ON.

3. The sensor assembly interface circuit of claim 1, wherein the one or more switches are initially closed upon start up of the band gap reference circuit.

4. The sensor assembly interface circuit of claim 1, wherein one of the first transistor and the second transistor is coupled to the associated circuit substrate via an additional resistance.

5. The sensor assembly interface circuit of claim 1, wherein the first and second transistors are coupled to the shared voltage source via a current mirror circuit.

6. The sensor assembly interface circuit of claim 5, wherein the current mirror circuit supplies matched current to the first and second transistors.

7. The sensor assembly interface circuit of claim 6, further comprising a cascade circuit coupling the current mirror circuit to the first and second transistors.

8. The sensor assembly interface circuit of claim 7, wherein the cascade circuit includes a pair of transistors, each one of the pair of transistors coupling a respective one of the first transistor and the second transistor to the current mirror circuit.

9. The sensor assembly interface circuit of claim 8, wherein one of the one or more switches comprises a start-up switch, which when closed provides a shunt across a cascade transistor of the pair of transistors, the cascade transistor being associated with the transistor coupled to the associated circuit substrate via an additional resistance.

10. The sensor assembly interface circuit of claim 1, wherein the first and second transistors are bipolar junction transistors.

11. The sensor assembly interface circuit of claim 10, wherein the first and second transistors are vertical NPN bipolar junction transistors and the corresponding parasitic transistors are vertical PNP bipolar junction transistors.

12. The sensor assembly interface circuit of claim 1, further comprising a charge pump, wherein a regulated band gap reference output voltage produced using the reference voltage generated by the band gap reference circuit is supplied to the charge pump.

13. The sensor assembly interface circuit of claim 12, wherein the charge pump is configured to produce a bias voltage for a microelectromechanical systems sensor.

14. The sensor assembly interface circuit of claim 1, further comprising a forward signal-path analog-to-digital converter located between and coupled to the analog front end amplifier or buffer and the output pad of the interface circuit, wherein a regulated band gap reference output voltage produced using the reference voltage generated by the band gap reference circuit is supplied to the analog-to-digital converter.
